(19) United States
(12) Patent Application Publication
(10) Pub. No.: US 2026/0333836 A1
(43) Pub. Date: Oct. 22, 2026

(54) DIPOLE DOPING FOR CFETS WITH REDUCED LOADING

(71) Applicant: Taiwan Semiconductor Manufacturing Co., Ltd., Hsinchu (TW)

(72) Inventors: Yi-Fan Huang, Hsinchu (TW); Hsin-Chih Wang, Zhubei City (TW); Hsin-Yuan Lee, Hsinchu (TW); Yu-Tien Shen, Tainan City (TW); Chih-Kai Yang, Taipei City (TW); Ming-Feng Shieh, Yongkang City (TW)

(21) Appl. No.: 19/725,239

(22) Filed: Jun. 30, 2026

Related U.S. Application Data
(63) Continuation of application No. 19/044,025, filed on Feb. 3, 2025.
(60) Provisional application No. 63/703,503, filed on Oct. 4, 2024.

(51) Int. Cl. H10D 84/01; H10D 84/85

(52) U.S. Cl. CPC H10D 84/0181; H10D 84/0167; H10D 84/017; H10D 84/851; H10D 84/856

(57) ABSTRACT

A method includes forming a lower semiconductor nanostructure and an upper semiconductor nanostructure overlying the lower semiconductor nanostructure, forming an upper gate dielectric and an upper gate dielectric on the lower semiconductor nanostructure and the upper semiconductor nanostructure, respectively, dispensing a directed self-assembly material to embed the lower semiconductor nanostructure and the upper semiconductor nanostructure therein, and annealing the directed self-assembly material to form dummy filling-regions. The dummy filling-regions include a first plurality of layers and a second plurality of layers located alternatingly. The dummy filling-regions are recessed, so that remaining portions of the dummy filling-regions include top surfaces lower than the upper semiconductor nanostructure. A dipole dopant is doped into one of the upper gate dielectric and the lower gate dielectric.

### PRIORITY CLAIM AND CROSS-REFERENCE

This application is a continuation of U.S. patent application Ser. No. 19/044,025 filed on Feb. 3, 2025, which application claims the benefit of the following provisionally filed U.S. Patent Application No. 63/703,503, filed on Oct. 4, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 22 are views of intermediate stages in the manufacturing of CFETs in accordance with some embodiments.

FIGS. 23 through 36 are views of intermediate stages in the manufacturing of CFETs in accordance with alternative embodiments.

FIG. 37 illustrates a process flow for forming a CFET in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and the method of forming the same are provided. In accordance with some embodiments, a CFET structure includes an upper FET and a lower FET. The threshold voltages of the upper FET and the lower FET are adjusted by doping dipole dopants into the respective gate dielectrics. A Directed Self-Assembly (DSA) material is used to assist the selective doping of the gate dielectrics of the upper FET and the lower FET. With the nature of the DSA material, the loading in the etching of the DSA is reduced, and the etching may be controlled to a desirable level accurately.

It is appreciated that while Gate-All-Around (GAA) transistors (such as nanostructure-FETs) are discussed, the concept of the present disclosure can also be applied to the formation of other types of transistors such as planar transistors, Fin Field-Effect Transistors (FinFETs), or the like. Throughout the description, the terms “FET” and “transistor” are used interchangeably.

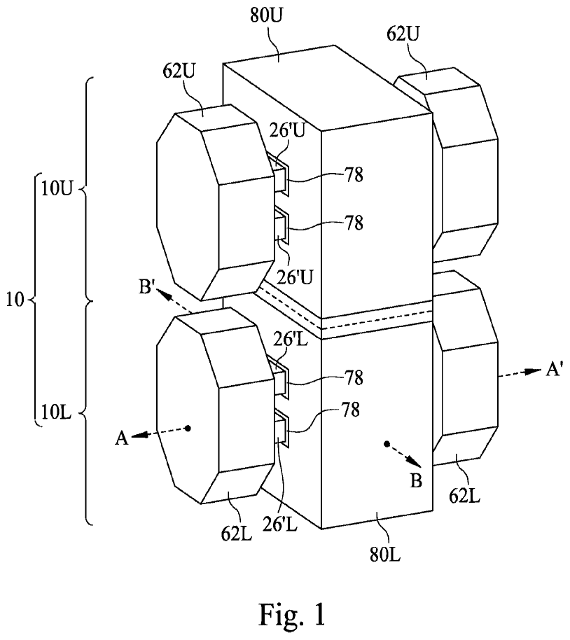

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite to the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and aligned with the direction of current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

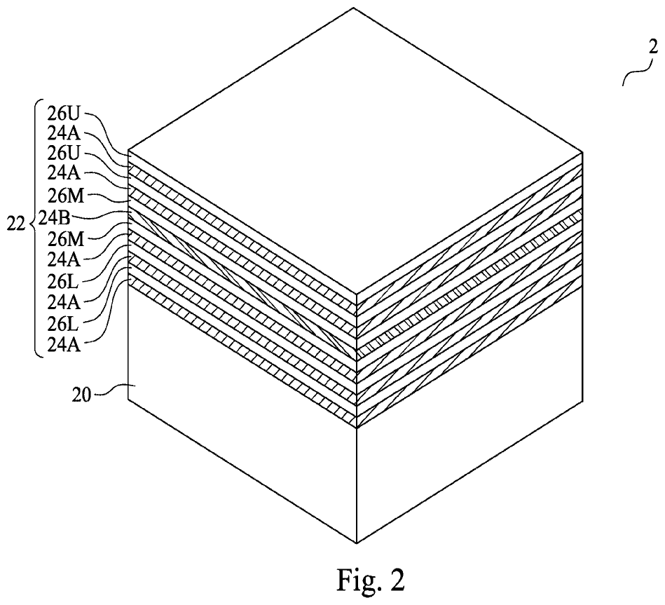

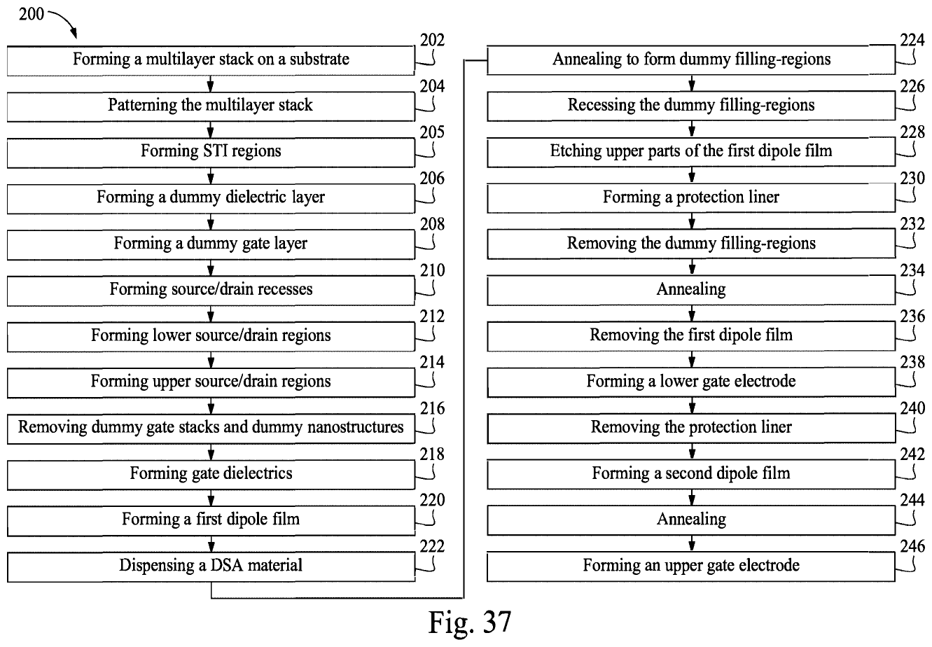

FIGS. 2 through 23 illustrate the cross-sectional views of intermediate stages in the formation of CFETs (as schematically represented in FIG. 1) in accordance with some embodiments. The corresponding processes are also reflected schematically in the process flow shown in FIG. 37. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

A multi-layer stack 22 is formed over the substrate 20. The respective process is illustrated as process 202 in the process flow 200 as shown in FIG. 37. The multi-layer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, and the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in dummy semiconductor layer 24A.

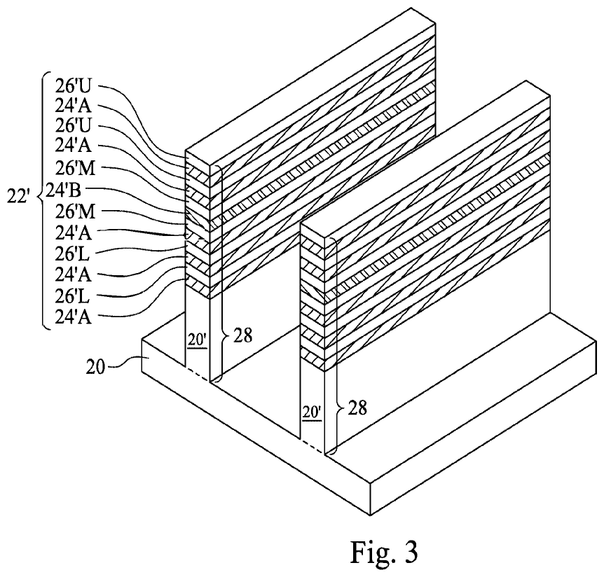

In FIG. 3, multi-layer stack 22 and substrate 20 are patterned to form semiconductor strips 28. The respective process is illustrated as process 204 in the process flow 200 as shown in FIG. 37. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

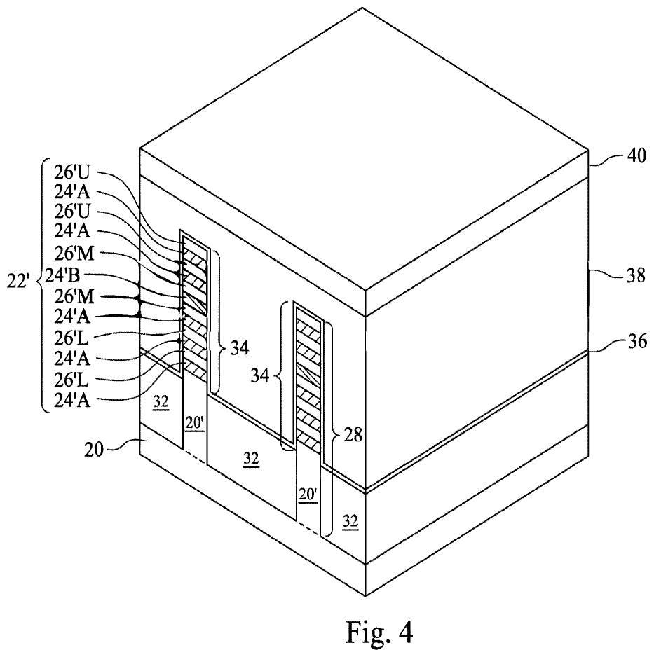

In FIG. 4, isolation regions 32 are formed over the substrate 20 and between adjacent semiconductor strips 28. The respective process is illustrated as process 205 in the process flow 200 as shown in FIG. 37. Isolation regions 32 may include a dielectric liner and a dielectric material over the dielectric liner. Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 37. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 37. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

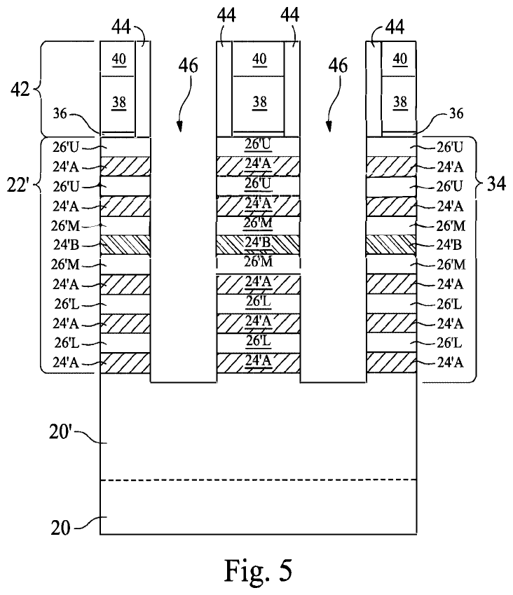

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Source/drain recesses 46 are then formed in semiconductor strips 28. The respective process is illustrated as process 210 in the process flow 200 as shown in FIG. 37. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

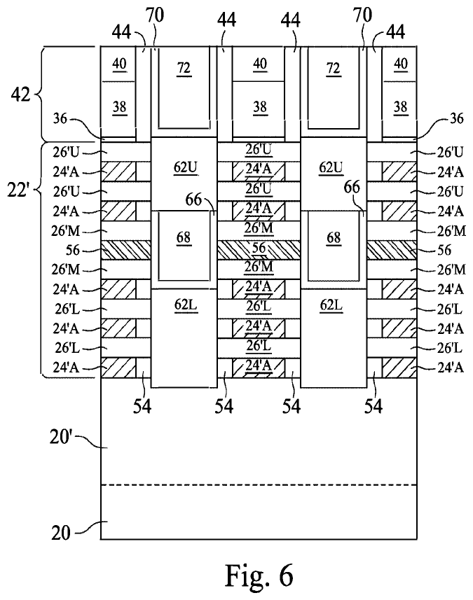

Dummy nanostructures 24′A are then laterally recessed, and a dielectric material is filled into the respective recesses to form inner spacers 54, which are dielectric spacers. The resulting structure is shown in FIG. 6. Dielectric isolation layers 56 are also formed to replace the dummy nanostructures 24′B.

Next, lower epitaxial source/drain regions 62L are formed in the lower portions of the source/drain recesses 46 (FIG. 5). The respective process is illustrated as process 212 in the process flow 200 as shown in FIG. 37. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants.

A first contact etch stop layer (CESL) 66 and a first interlayer dielectric (ILD) 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or flowable CVD (FCVD). The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The respective process is illustrated as process 214 in the process flow 200 as shown in FIG. 37. The materials of upper epitaxial source/drain regions 62U may be selected from the same candidate group of materials for forming lower epitaxial source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove mask layers 40, or leave hard mask layers 40 unremoved.

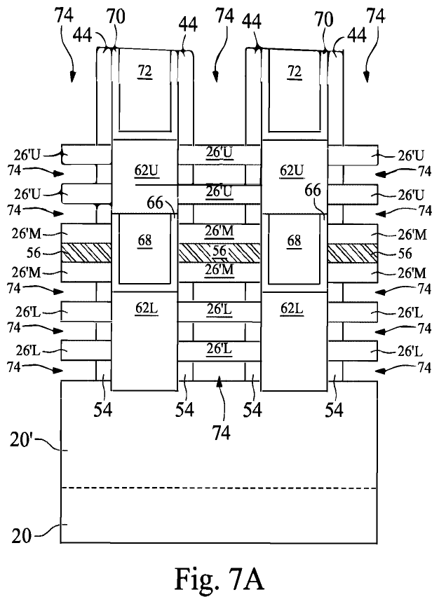

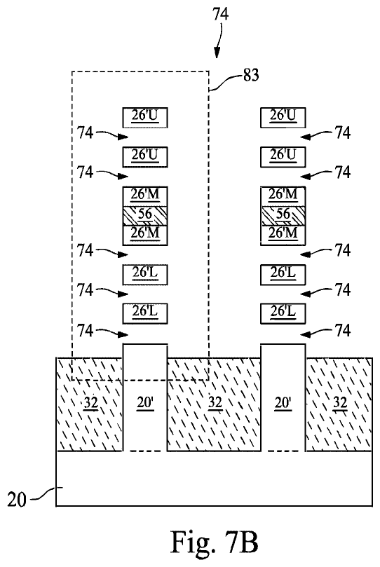

The dummy gate stacks 42 are then removed in one or more etching processes, so that recesses 74 are formed, as shown in FIGS. 7A and 7B. Each of recesses 74 exposes and/or overlies portions of multi-layer stacks 22′ (FIG. 6). The respective process is illustrated as process 216 in the process flow 200 as shown in FIG. 37.

The remaining portions of the dummy nanostructures 24′A (FIG. 6) are then removed through etching, so that recesses 74 extend between the semiconductor nanostructures 26′. The respective process is also illustrated as process 216 in the process flow 200 as shown in FIG. 37. In the etching process, the dummy nanostructures 24′A is etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

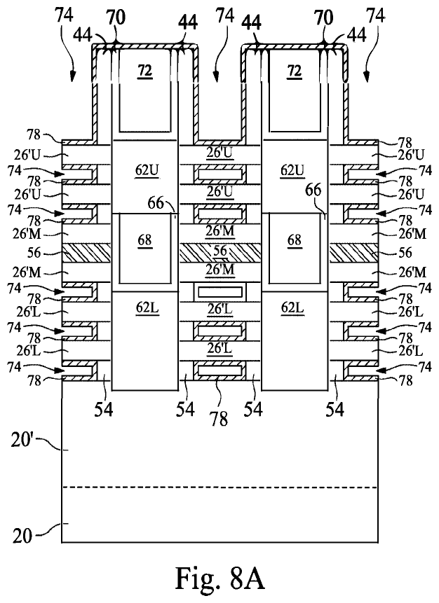

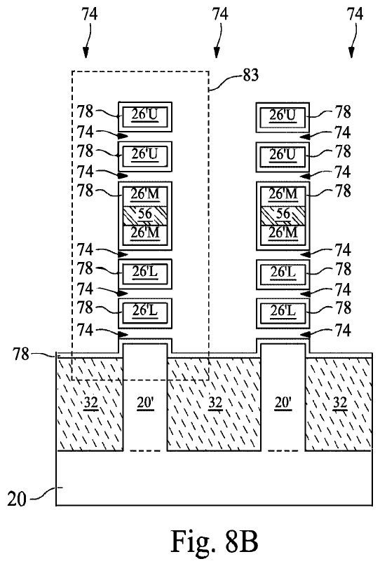

In FIGS. 8A and 8B, gate dielectrics 78 are formed in recesses 74, and are formed on the exposed semiconductor nanostructures 26′. The respective process is illustrated as process 218 in the process flow 200 as shown in FIG. 37. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

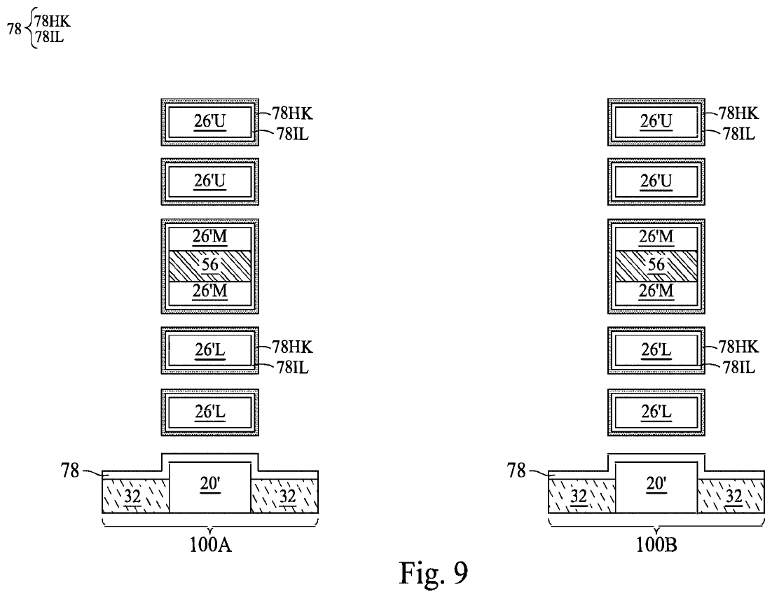

FIGS. 9-21 illustrate the details for forming gate dielectrics 78 and gate electrodes 80 (including 80U and 80L) in accordance with some embodiments. Referring to FIG. 9, two device regions 100A and 100B are illustrated. Each of the device regions 100A and 100B is for forming a CFET including an upper FET and a lower FET. Each of the device regions 100A and 100B may be obtained from the region 83 as shown in FIG. 8B. In the illustrated example, the upper FETs that are being formed are NFETs, and the lower FETs that are being formed are PFETs. In accordance with alternative embodiments, PFETs may be formed as the upper FETs, and NFET may be formed as lower FETs.

In accordance with some embodiment, device region 100A is a pattern-sparse region, for example, with fewer CFETs formed per unit area, and device region 100B is a pattern-dense region, for example, with more CFETs formed per unit area than in the pattern-sparse region. The spacing between the neighboring CFETs in device region 100B may also be smaller than the spacing between the neighboring CFETs in device region 100A.

Referring again to FIG. 9, gate dielectrics 78 encircle nanostructures 26′U, 26M, and 26′L. The gate dielectrics 78 in device regions 100A and 100B are formed in common processes. Each of the gate dielectrics 78 may include an interfacial layer 78IL, which may include an oxide such as silicon oxide. The interfacial layer 78IL may be formed through a thermal oxidation process and/or a deposition process.

The gate dielectrics 78 may also include high-k dielectric layers 78HK, which have a high dielectric constant (high-k) value greater than, for example, about 7.0, about 21, or higher. High-k dielectric layers 78HK may be formed of or comprise a metal oxide or a silicate of a metal selected from hafnium, zirconium, barium, titanium, lead, and combinations thereof. The formation methods of high-k dielectric layers 78HK may be selected from Molecular-Beam Deposition (MBD), ALD, PECVD, and the like.

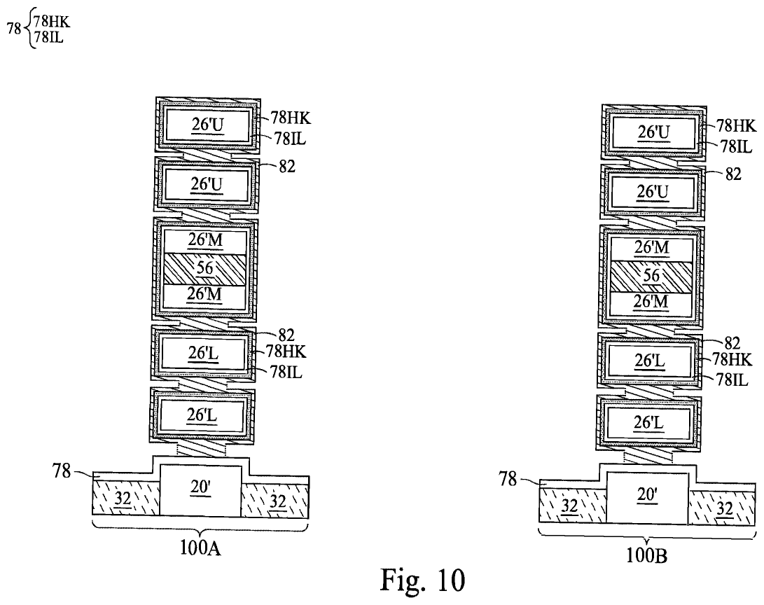

Referring to FIG. 10, dipole films 82 are deposited on the gate dielectrics 78 in device regions 100A and 100B. The respective process is illustrated as process 220 in the process flow 200 as shown in FIG. 37. Dipole films 82 may be formed through a deposition process, which may be, or may not be, followed by an etching process. The portions of dipole films 82 joining neighboring gate dielectrics 78 may or may not exist, and are thus illustrated as being dashed. It is appreciated that dipole films 82 and subsequently deposited films may also include horizontal portions on the top surface of the gate dielectric 78 that is formed on the isolation regions 32 and semiconductor strips 20′. These portions of the dipole films 82 are not illustrated for the simplicity of views.

Dipole films 82 may comprise a dipole dopant desirable by the gate dielectrics 78 of the lower FET. The dipole dopants, when incorporated into the gate dielectrics 78 of the lower FETs, may increase the effective work functions (when the lower FETs are p-type FETs) and hence reduce the threshold voltages of the corresponding lower FETs. In accordance with some embodiments, dipole films 82 may comprise a material selected from one or more of an oxide(s), a nitride(s), and/or a carbide(s) of a p-type dipole dopant(s) such as Al, Ga, Zn, Ti, Ta, or the like, or combinations thereof.

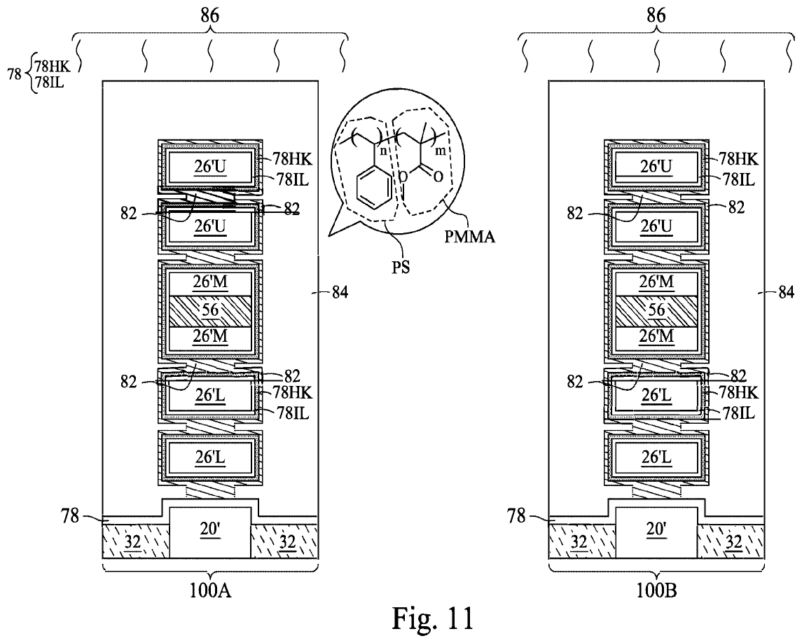

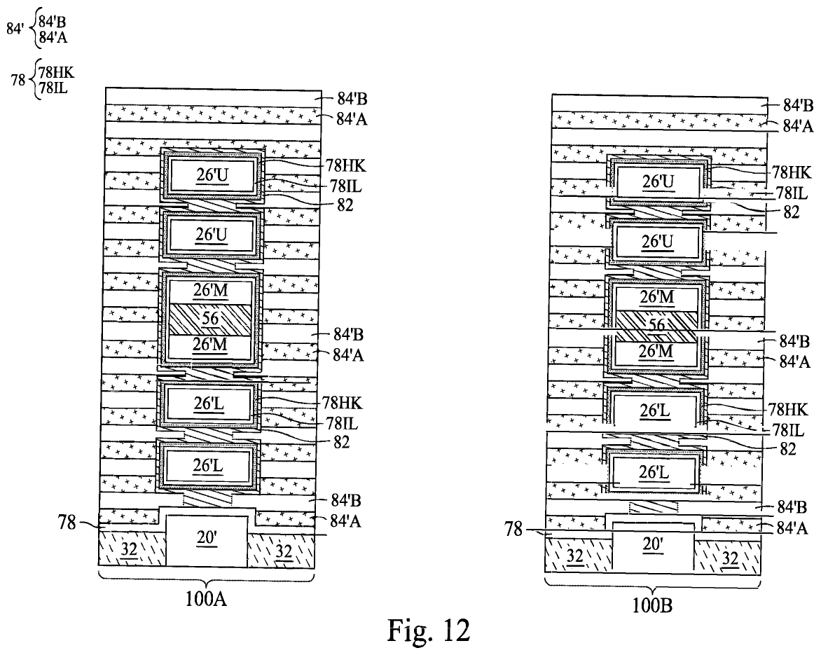

FIGS. 11 and 12 illustrate the formation of dummy filling-regions 84′, which are sacrificial regions, in device regions 100A and 100B. In accordance with some embodiments, as shown in FIG. 11, dummy filling-regions 84 are formed, for example, dispensed. The respective process is illustrated as process 222 in the process flow 200 as shown in FIG. 37.

Dummy filling-regions 84 may be formed of or comprise a DSA material, which is capable of being separated into a plurality of layers. In accordance with some embodiments, the DSA material includes a block copolymer. The block copolymer may include poly(styrene) (PS) and poly(methyl methacrylate) (PMMA), which form a block material by forming bonding with each other. For example, FIG. 11 illustrates an example of a portion of the PS bonding to a portion of PMMA. The block material of the PS and PMMA may also be denoted as poly(styrene)-block-poly (methyl methacrylate) (PS-b-PMMA).

The block copolymer may be in a solvent and thus is flowable. The solvent may comprise toluene, tetrahydrofuran, and/or the like. Accordingly, dummy filling-regions 84 are formed by coating (using, for example, spin-coating) a mixture of the DSA material in the solvent. Dummy filling-region 84 may have a planar top surface within process variation.

An annealing process 86 is then performed to cure the DSA material. The respective process is illustrated as process 224 in the process flow 200 as shown in FIG. 37. In accordance with some embodiments, the annealing process 86 is performed at a temperature in a range between about 150 °C and about 450 °C. The annealing duration may be in the range between about 1 minutes and about 180 minutes.

As the result of the annealing process 86, the solvent evaporates, and phase separation occurs. The resulting structure is shown in FIG. 12, wherein the phase-separated dummy filling-regions 84 are denoted as dummy filling-regions 84′. Dummy filling-regions 84′ have a lamellar structure comprising layers 84′A and 84′B that are located alternatingly.

In accordance with some embodiments, high-k dielectric layer 78HK is hydrophilic, and hence the phase separation is in the horizontal direction. The phase separation may occur at the gate dielectric 78 that is on dielectric isolation regions 32 and propagate to other portions of the dummy filling-regions 84′.

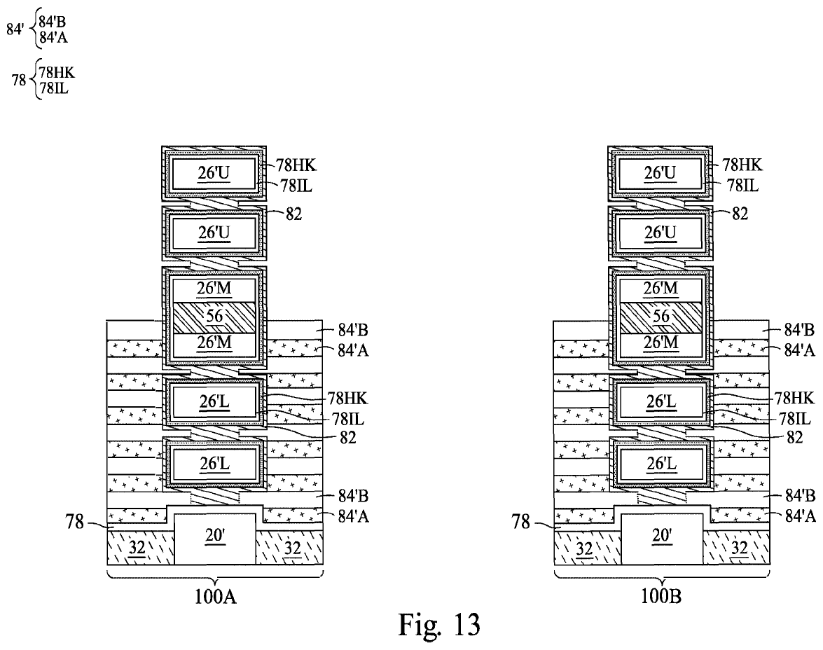

In accordance with some embodiments in which the block copolymer comprises PS-b-PMMA, layers 84′A comprise PMMA since PMMA favors hydrophilic surfaces. Layers 84′B comprise PS accordingly. In accordance with some embodiments, the thickness of layers 84′A and 84′B are equal to or smaller than the thickness (for example, smaller than about 6 nm) of dielectric isolation layers 56. Advantageously, in subsequent etch-back process as shown in FIG. 13, the top surface of the remaining dummy filling-regions 84′ may be controlled to be at a level between the top surface level and the bottom surface level of dielectric isolation layers 56. The adjustment of the thicknesses of layers 84′A and 84′B may be achieved, for example, by controlling the sizes of the PS and PMMA molecules in the PS-b-PMMA.

In accordance with some embodiments, after the annealing process 86, a CMP process may be performed to thin the dummy filling-regions 84′, so that the top surfaces of dummy filling-regions 84′ are slightly higher than the top most one of the semiconductor layers 26′U. This will reduce the needed number of cycles of the subsequent etch-back process.

Referring to FIG. 13, an etch-back (recessing) process is performed. The etching back process includes a plurality of cycles, each including etching layer 84′A and etching layer 84′B. The respective process is illustrated as process 226 in the process flow 200 as shown in FIG. 37. In accordance with some embodiments in which layers 84′A and 84′B comprise PMMA and PS, respectively, the PMMA may be etched using acetic acid, and the PS may be etched using cyclehexane.

In the etching of layer 84′A, layer 84′B is used as the etch stop layer. In the etching of layer 84′B, layer 84′A is used as the etch stop layer. Therefore, through the etching of layers 84′A and 84′B alternatingly, the etching depth may be accurately controlled, and the accuracy of the etching process is determined by the thicknesses of layers 84′A and 84′B.

As shown in FIG. 13, the etch-back process is controlled, so that the top surface of the remaining dummy filling-regions 84′ is lower than the top surface of, and higher than the bottom surfaces of, the dielectric isolation layers 56. The top surface of the remaining dummy filling-regions 84′ may also be slightly higher or lower to be level with the middle semiconductor nanostructures 26′M.

Since the stopping of each cycle in the etch-back process is determined by the layers 84′A and 84′B, pattern density no longer affects the loading of the etching process. The loading between the pattern-sparse region (device region) 100A and the pattern-dense region (device region) 100B is thus eliminated or at least reduced. Accordingly, the top surface of the dummy filling-region 84′ in device region 100A may be level with the top surface of the dummy filling-region 84′ in device region 100B.

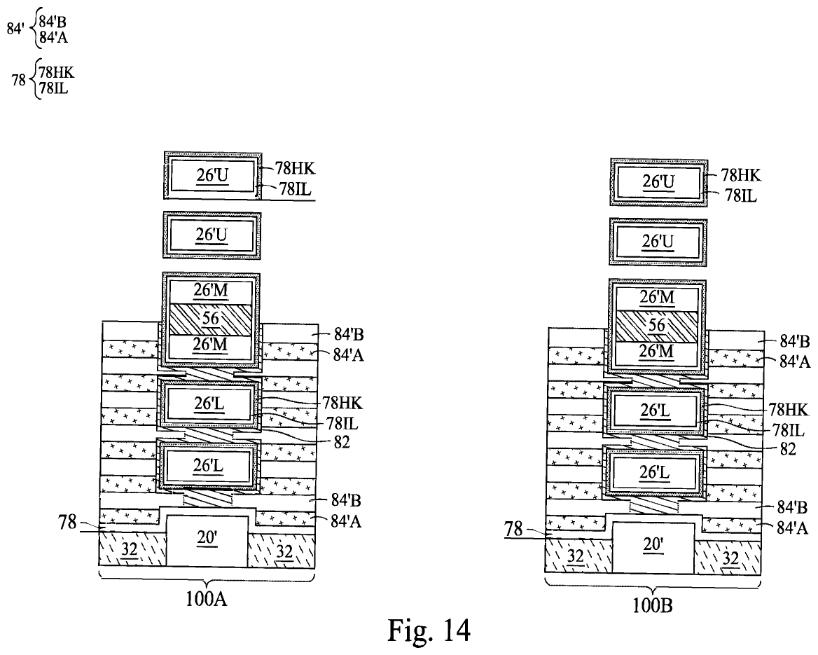

Next, an isotropic etching process is performed to remove upper portions of dipole films 82, and the resulting structure is shown in FIG. 14. The respective process is illustrated as process 228 in the process flow 200 as shown in FIG. 37. The etching process may be a wet etching process or a dry etching process, and is isotropic. The etching chemical is selected to etch dipole films 82, and the etching stops on high-k dielectric layers 78HK. Accordingly, the portions of dipole films 82 on upper semiconductor nanostructures 26′U and the upper one of the middle semiconductor nanostructures 26′M are removed. The portions of dipole films 82 on lower semiconductor nanostructures 26′L and the lower one of the middle semiconductor nanostructures 26′M are protected from being removed.

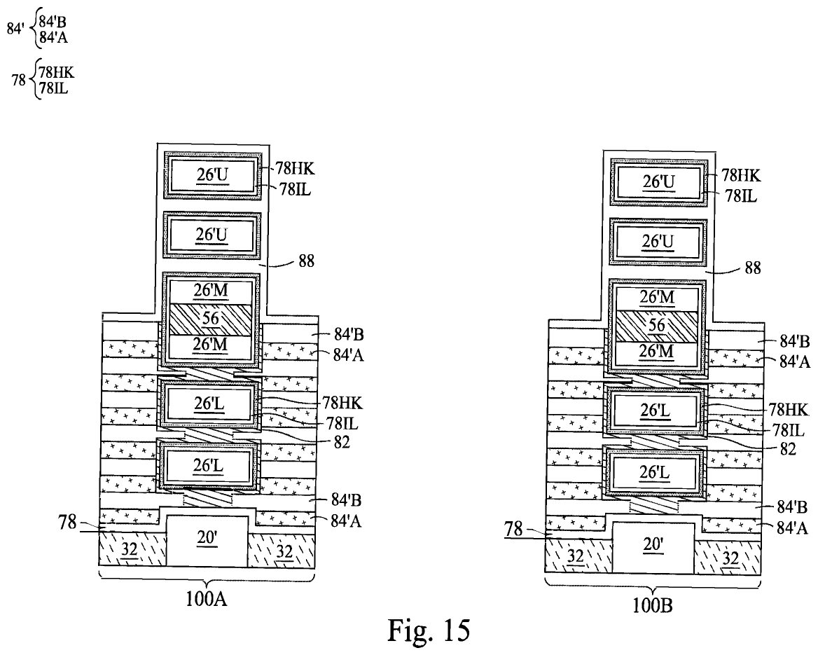

FIG. 15 illustrates the formation of protection liner 88. The respective process is illustrated as process 230 in the process flow 200 as shown in FIG. 37. The formation process may include a conformal deposition process, for example, a CVD process, an ALD process, or the like. The protection liner 88 may comprise silicon oxide, silicon nitride, silicon oxynitride, silicon carbide, aluminum oxide, aluminum nitride, or the like, or combinations thereof.

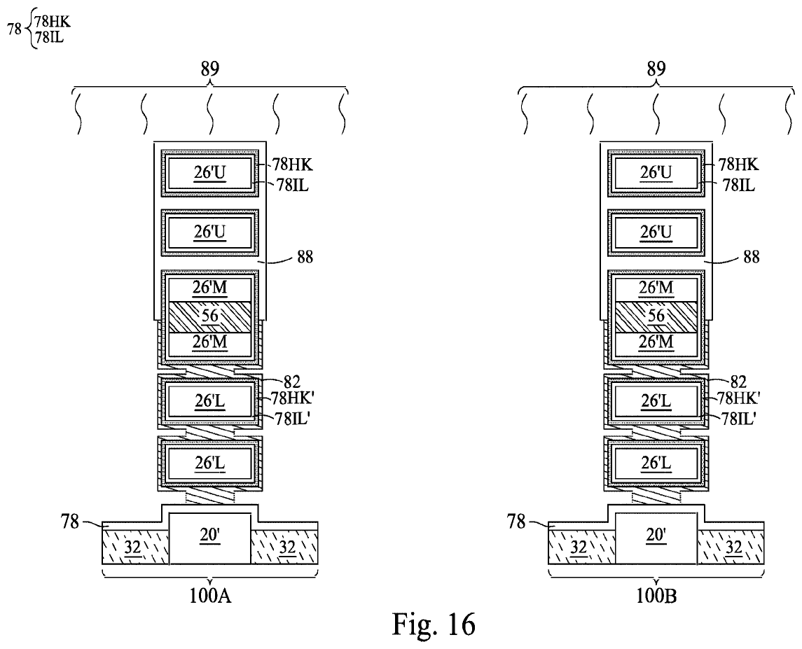

Next, an anisotropic etching process is performed to remove the horizontal portions of the protection liner 88 on the top surfaces of dummy filling-regions 84′. The resulting structure is shown in FIG. 16. Dummy filling-regions 84′ are thus exposed. In a subsequent process, a plurality of etching cycles are performed to remove layers 84′A and 84′B alternatingly, until all of the dummy filling-regions 84′ are removed. The respective process is illustrated as process 232 in the process flow 200 as shown in FIG. 37. In accordance with alternative embodiments, the dummy filling-regions 84′ are removed through a single etching process by using an etching chemical that may etch both of layers 84′A and 84′B.

Further referring to FIG. 16, annealing process 89 is performed to drive the dipole dopants in the dipole films 82 into the respective underlying gate dielectrics 78. The respective process is illustrated as process 234 in the process flow 200 as shown in FIG. 37. The annealing process 89 may be performed in a process gas selected from N₂, He, NH₃, Ar, and the like, and the mixtures thereof. The annealing results in the dipole dopant in the dipole films 82 to be driven into the respective underlying high-k dielectric layer 78HK, and possibly interfacial layer 78IL. This has the effect of adjusting (such as reducing) the threshold voltages of the resulting lower FETs. The resulting doped interfacial layers 78IL and high-k dielectric layers 78HK are referred to as interfacial layers 78IL′ and high-k dielectric layers 78HK′, respectively.

In accordance with some embodiments, annealing process 89 is performed through a soak annealing process, a spike rapid thermal annealing process, or the like. When the soak annealing process is adopted, the annealing duration may be in the range between about 5 seconds and about 5 minutes. The annealing temperature may be in the range between about 500 °C and about 850 °C

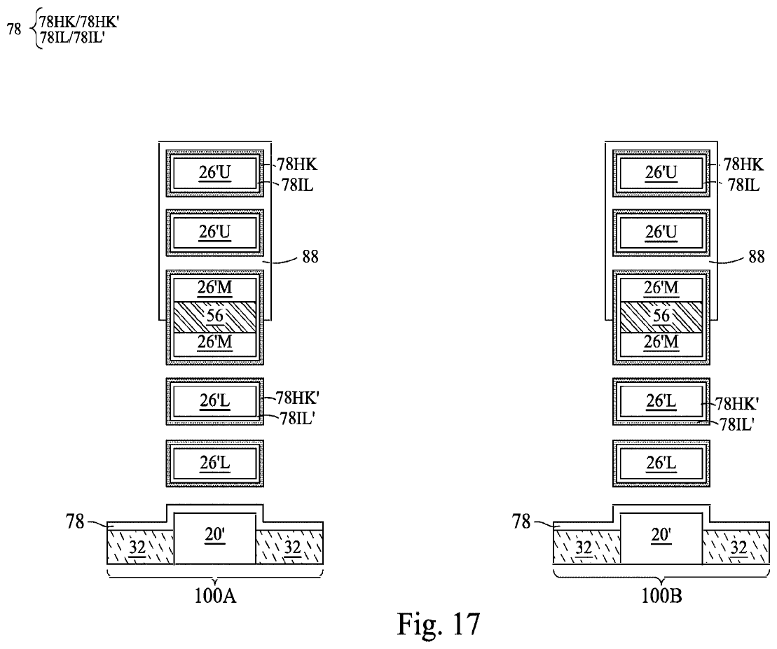

Dipole films 82 are then removed in an isotropic etching process. The respective process is illustrated as process 236 in the process flow 200 as shown in FIG. 37. The resulting structure is shown in FIG. 17, wherein high-k dielectric layers 78HK′ are exposed.

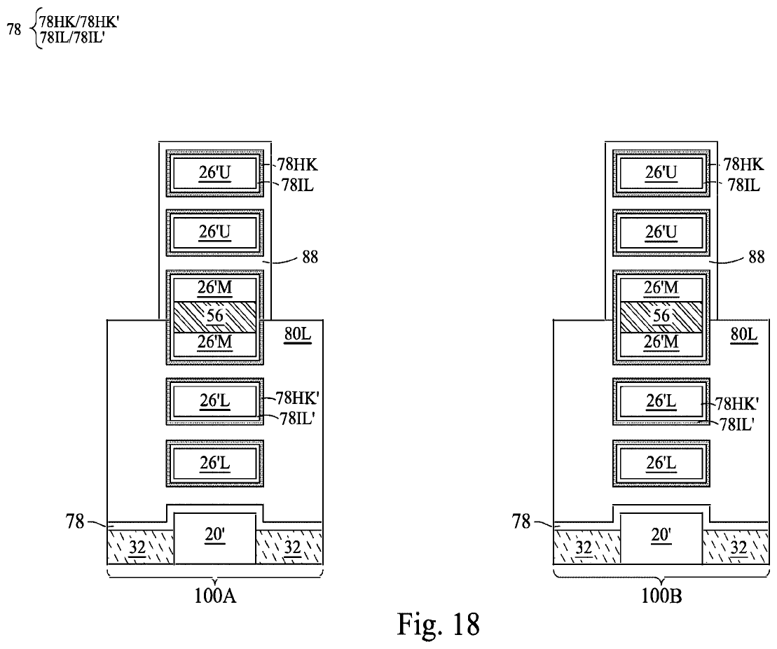

FIG. 18 illustrates the formation of lower gate electrodes 80L. The respective process is illustrated as process 238 in the process flow 200 as shown in FIG. 37. Gate dielectrics 78 and the respective lower gate electrodes 80L are collectively referred to as gate stacks 90L. Lower gate electrodes 80L may include a work function layer, which has a work function suitable for the conductivity type of the lower FET. Lower gate electrodes 80L may or may not include a filling metal such as tungsten, cobalt, or the like. Lower transistor 10L is thus formed.

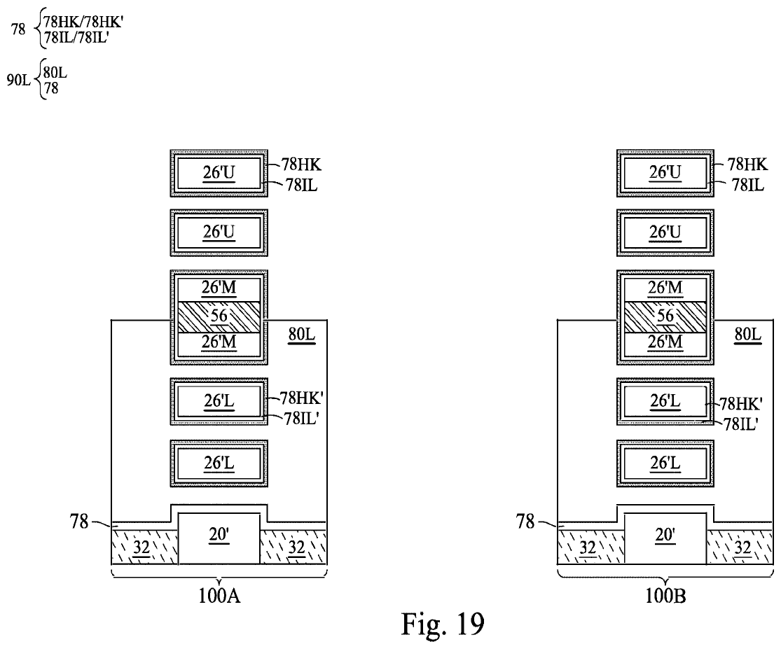

Protection liner 88 is then removed, and the resulting structure is shown in FIG. 19. The respective process is illustrated as process 240 in the process flow 200 as shown in FIG. 37. In accordance with some embodiments, as shown in preceding figures, protection liner 88 is removed after the formation of the lower gate electrodes 80L. In accordance with alternative embodiments, protection liner 88 may also be removed before the formation of the lower gate electrodes 80L.

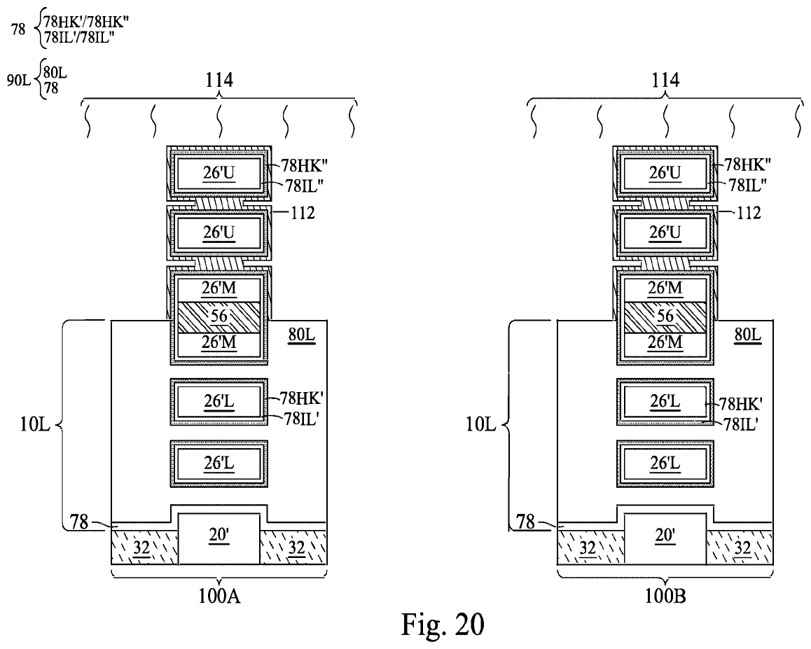

FIG. 20 illustrates the dipole doping of the gate dielectrics 78 of the upper FETs in accordance with some embodiments. Dipole films 112 are deposited on the gate dielectrics 78 in device regions 100A and 100B, respectively, and encircling the upper semiconductor nanostructures 26′U. The respective process is illustrated as process 242 in the process flow 200 as shown in FIG. 37. Dipole films 112 comprises dipole dopant desirable by the upper FET, which when incorporated into the gate dielectrics of upper FETs, may cause the reduction of the threshold voltages of the corresponding upper FETs.

In accordance with some embodiments, dipole films 112 may comprise an n-type dopant, and may include a material selected from one or more of an oxide(s), a nitride(s), and/or a carbide(s) of La, Sr, Y, Er, Sc, Mg, or the like, or combinations thereof. Dipole films 112 may be formed through a deposition process, (such as ALD, CVD, or the like), which may be or may not be conformal, and may or may not be followed by an etch back process.

Further referring to FIG. 20, annealing process 114 is performed to drive the dipole dopants in the dipole films 112 into the respective underlying high-k dielectric layers 78HK. The respective process is illustrated as process 244 in the process flow 200 as shown in FIG. 37. The process conditions of annealing process 114 may be selected from the same group of candidate process conditions of annealing process 89 (FIG. 16), and hence are not repeated herein.

The annealing results in the dipole dopant in the dipole films 112 to be driven into the respective underlying high-k dielectric layer 78HK, and possible interfacial layer 78IL. The resulting high-k dielectric layer and interfacial layer are referred to as high-k dielectric layer 78HK″ and interfacial layer 78IL″, respectively. Dipole films 112 are then removed in an isotropic etching process. In the resulting structure, high-k dielectric layers 78HK″ are exposed.

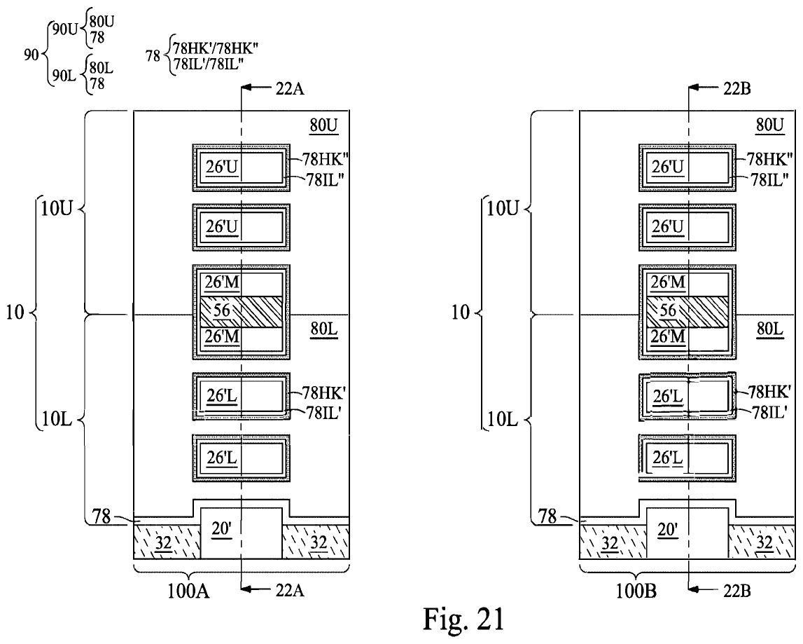

FIG. 21 illustrates the formation of upper gate electrodes 80U. The respective process is illustrated as process 246 in the process flow 200 as shown in FIG. 37. Gate dielectrics 78 and the respective upper gate electrodes 80U are collectively referred to as gate stacks 90U. Upper gate electrodes 80U may include a plurality of layers include TiN, TaN, or the like, and may include one or more work function layers. Upper FET 10U is thus formed. Upper FET 10U and lower FET 10L collectively form CFET 10.

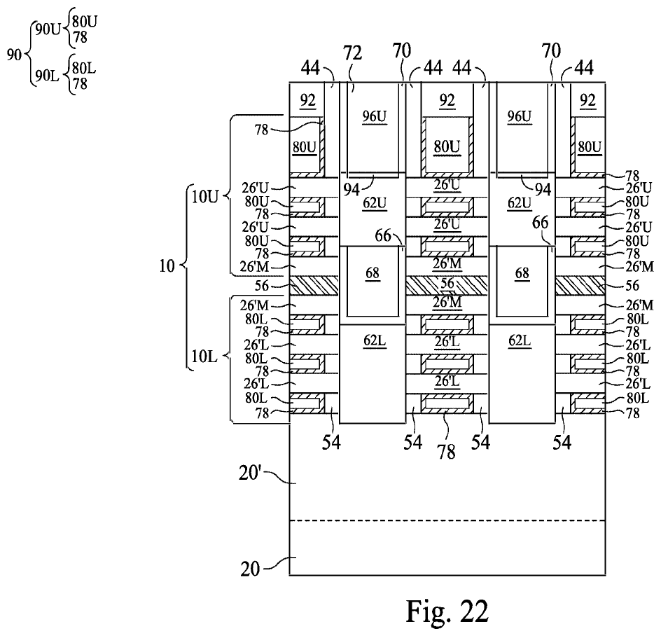

FIG. 22 illustrates a cross-sectional view of an example CFET formed in preceding processes, wherein the illustrated cross-sectional view may be obtained from cross-section 22A-22A or 22B-22B in FIG. 21. Each of the CFETs in device regions 100A and 100B as aforementioned may be represented by the CFET shown in FIG. 22. As shown in FIG. 22, gate masks 92 are further formed over the gate stacks 90. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72. Silicide regions 94 and source/drain contact plugs 96U are formed to electrically couple to the upper epitaxial source/drain regions 62U.

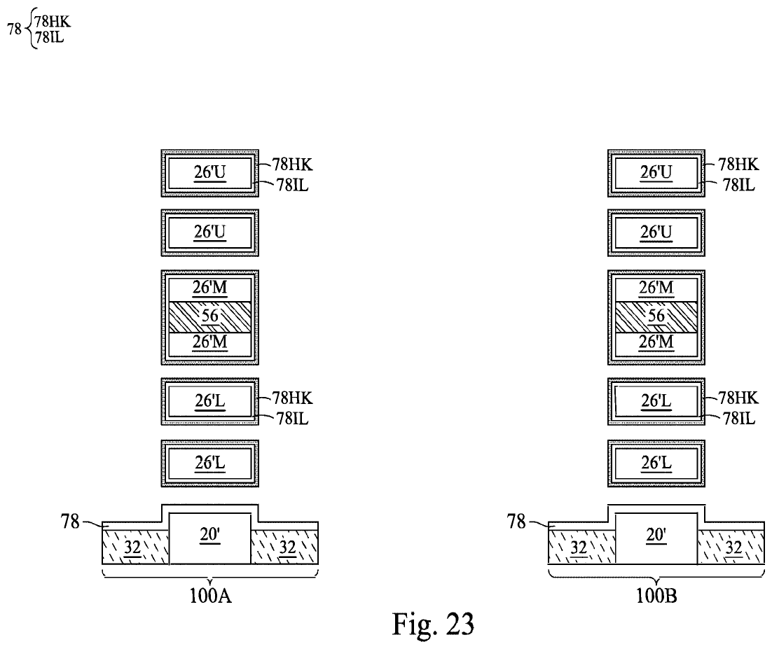

FIGS. 23 through 35 illustrate the cross-sectional views of intermediate stages in the formation of CFETs in accordance with alternative embodiments of the present disclosure. These embodiments are similar to the embodiments as shown in FIGS. 1 through 22, except that the upper FET are also doped differently, with one upper FET formed with dipole dopants doped therein, and the other upper FET formed without adopting dipole doping. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

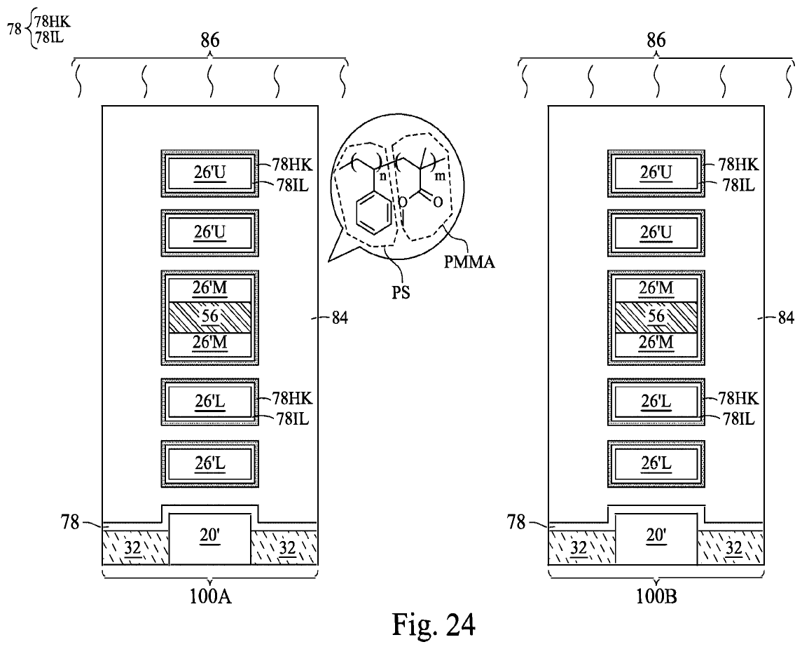

The initial steps of these embodiments are essentially the same as shown in FIGS. 1-9, and the resulting structure is shown in FIG. 23, which structure is essentially the same as that in FIG. 9. Next, as shown in FIG. 24, dummy filling-regions 84 are formed. The material and the formation process of dummy filling-regions 84 may be selected from the same candidate materials and formation methods as discussed referring to the preceding embodiments, and thus are not repeated herein. For example, dummy filling-regions 84 may be formed of a DSA material, and may include PS-b-PMMA in accordance with some embodiments. Dummy filling-regions 84 may be planarized, for example, in a CMP process or a mechanical grinding process.

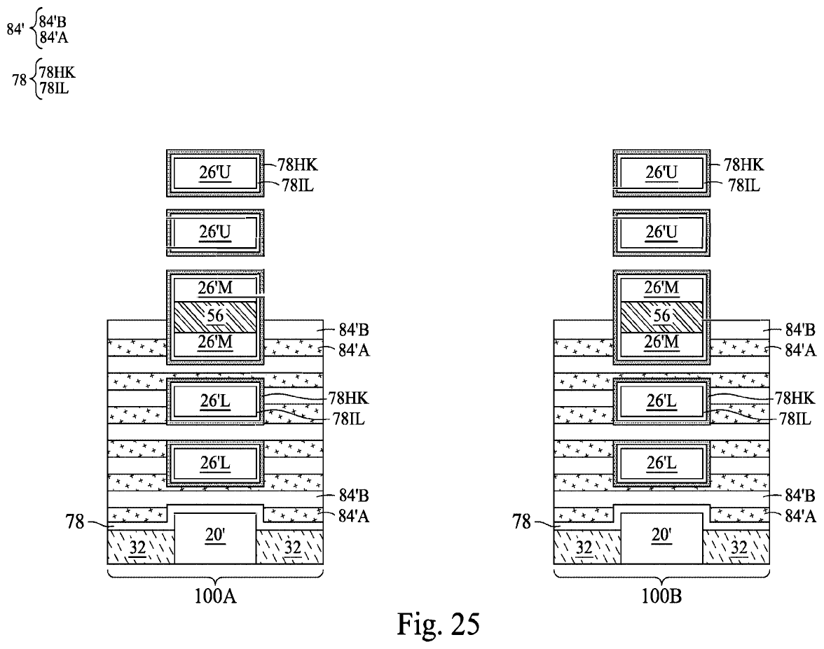

Annealing process 86 is then performed to convert dummy filling-regions 84 into dummy filling-regions 84′, which have a lamellar structure. The lamellar structure consists a plurality of layers 84′A and 84′B, with the alternating layer having the same material (such as PMMA or PS), and neighboring layers formed of different materials. A plurality of etching cycles are then performed to recess dummy filling-regions 84′ to the same level of dielectric isolation layers 56. The resulting structure is shown in FIG. 25.

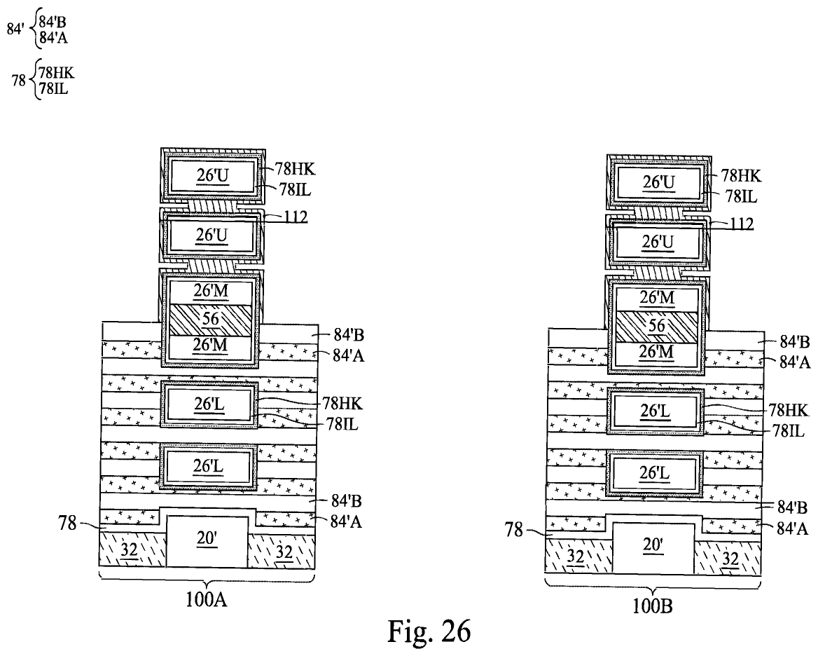

FIG. 26 illustrates the formation of dipole films 112. The material, the structure, and the formation methods of dipole films 112 may be essentially the same as discussed referring to FIG. 20, and are not repeated herein.

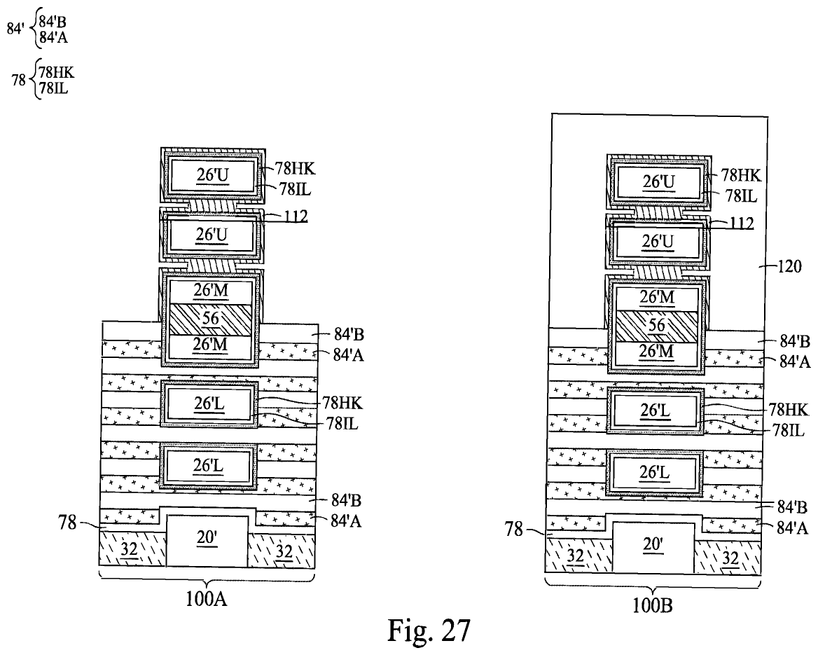

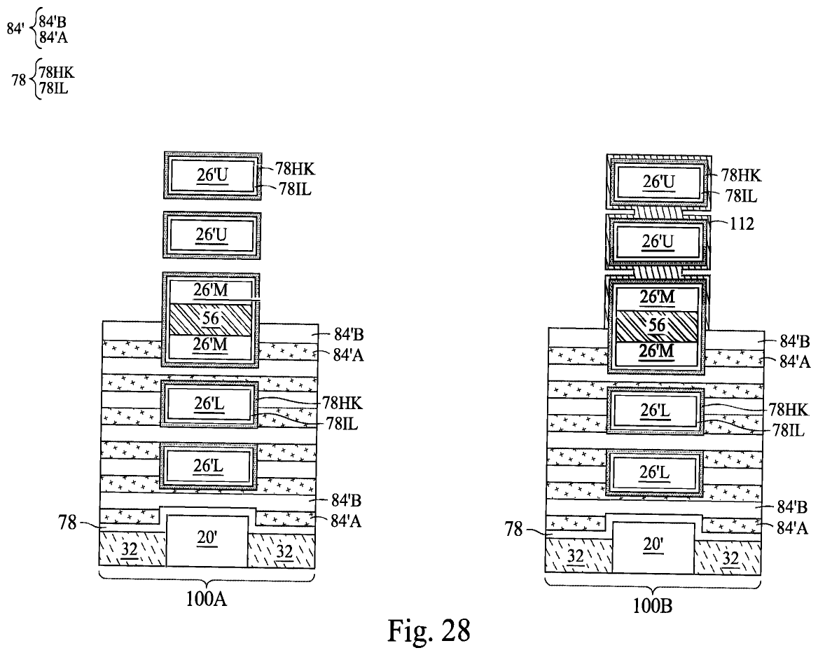

Referring to FIG. 27, etching mask 120 is formed. Etching mask 120 may include a hard mask, which may comprise AlO, AlN, BN, TiN, SiO, SiN, SiC, SiON, or the like. Etching mask 120 accordingly is interchangeably referred to as a hard mask. The formation process may include depositing hard mask 120 as a blanket layer, and removing hard mask 120 from device region 100A through a photolithography process. Etching mask 120 is then used to remove the portions of dipole films 112 from device region 100A through an etching process. The resulting structure is shown in FIG. 28.

In accordance with some embodiments, since the top surface of dipole films 112 may accurately stop at a desirable level, regardless of whether the etching mask 120 is formed in a pattern-sparse region or a pattern-dense region, the remaining portions of dipole films 112 may be accurately formed on all of the desirable upper semiconductor nanostructures 26′U, and will not be formed on any of the lower semiconductor nanostructures 26′L.

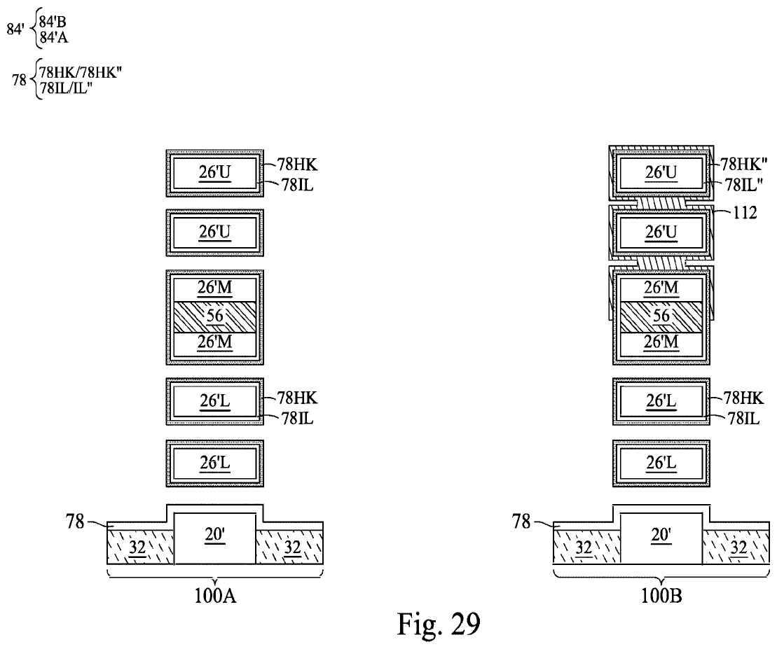

Etching mask 120 is then removed, and the resulting structure is also shown in FIG. 28. Dummy filling-regions 84′ are then removed in a plurality of etching cycles, resulting in the structure as shown in FIG. 29. The etching process may be essentially the same as the recessing of dummy filling-regions 84′ as shown in FIGS. 12 and 13.

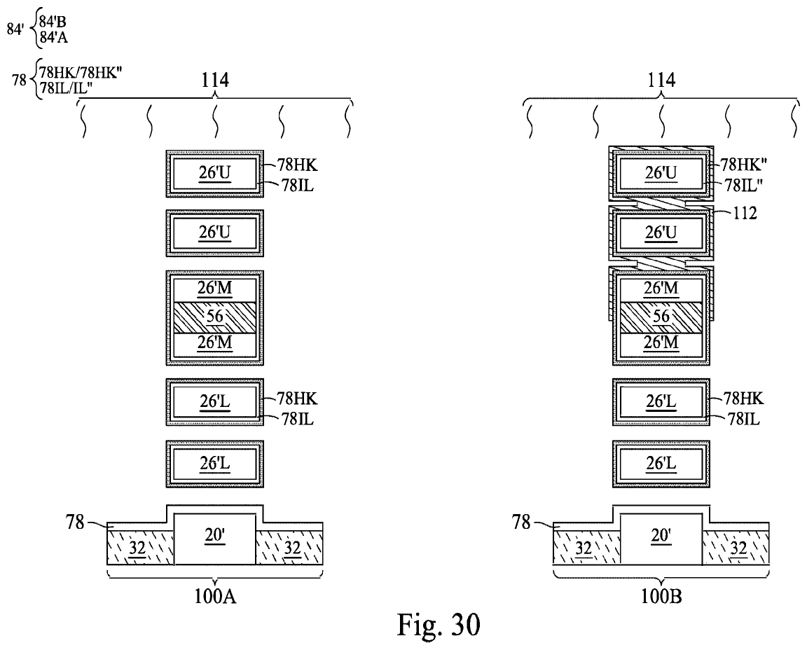

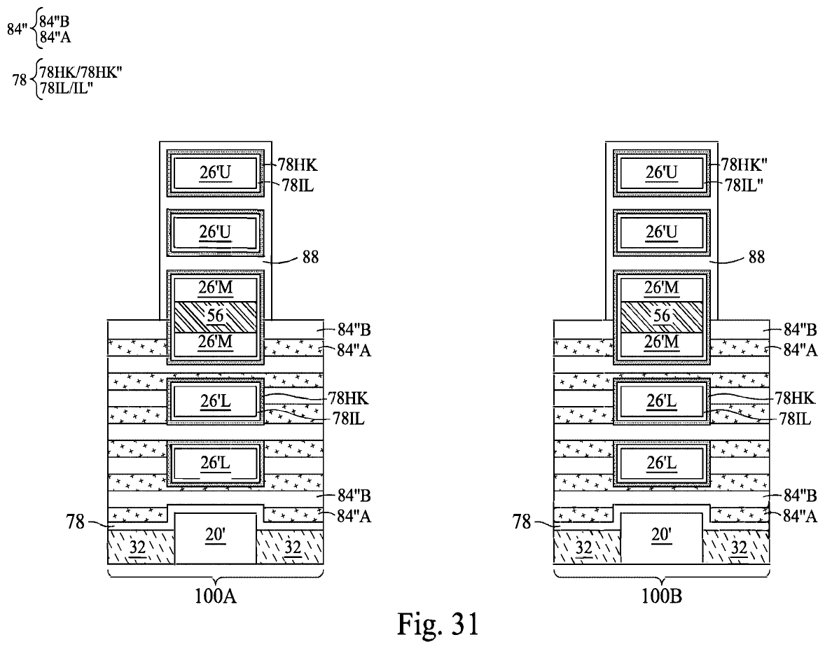

Referring to FIG. 30, annealing process 114 is performed to drive the dipole dopant in dipole film 112 into the respective underlying high-k dielectric layers and interfacial layers, forming high-k dielectric layers 78HK″ and interfacial layers 78IL″, respectively. In accordance with some embodiments, as illustrated, the annealing process 114 may be performed after the removal of the hard mask 120. In accordance with alternative embodiments, the order of the annealing process 114 and the removal of the hard mask 120 may be inversed, and the annealing process 114 may be performed before the removal of the hard mask 120. After the annealing process, dipole film 112 is removed through an etching process, and the resulting structure is shown in FIG. 31.

FIGS. 31 through 35 illustrates the dipole doping on the gate dielectrics 78 that are on the lower semiconductor nanostructures 26′L. These processes are similar to the process shown in FIGS. 15 through 20. A brief process is briefly discussed. The details are not repeated herein, and may be found referring to the discussion of the processes in FIGS. 15 through 20.

FIG. 31 illustrates the formation of dummy filling-regions 84″. The formation process may include dispensing a DSA material, and annealing the DSA material to form alternating layers 84″A and 84″B, which may include PMMA layers and PS layers, or other materials. The dummy filling-regions 84″ are then recessed in a plurality of recessing cycles.

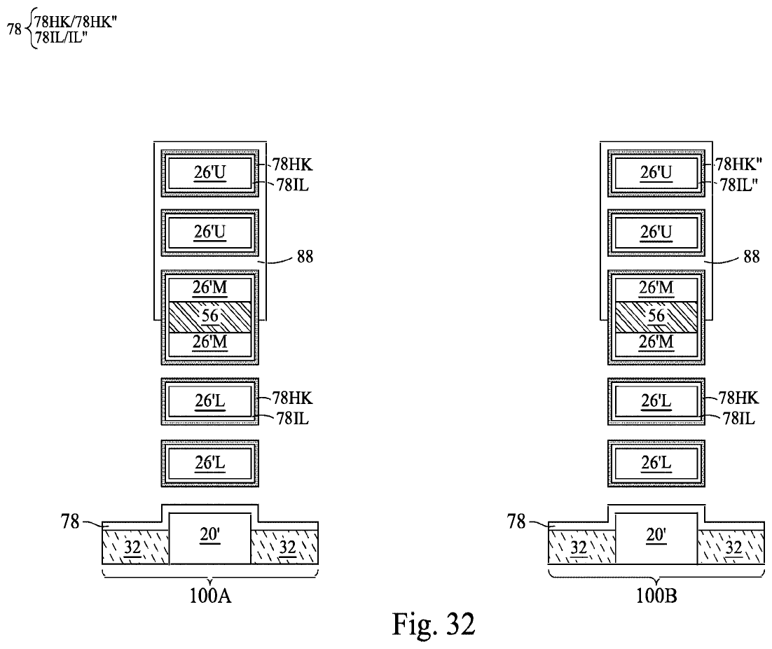

FIG. 31 further illustrates the formation of protection liner 88. The bottom of the protection liner 88 is defined by the top surface of dummy filling-regions 84″. Dummy filling-regions 84″ are then removed. The resulting structure is shown in FIG. 32.

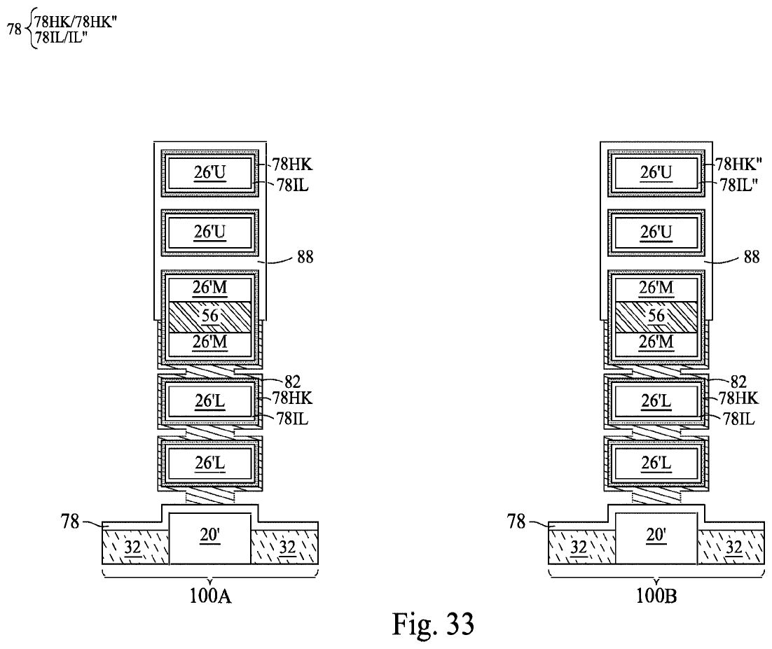

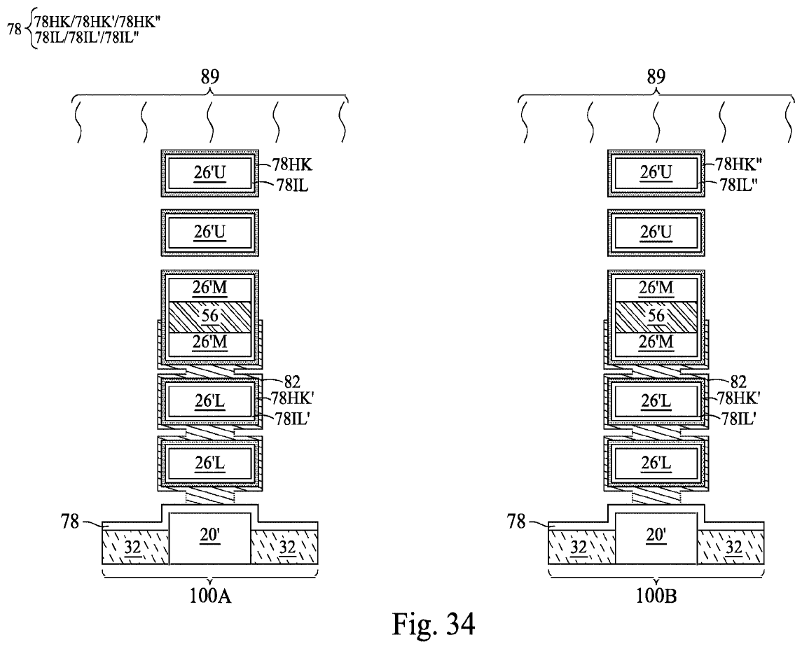

Next, as shown in FIG. 33, dipole film 82 is formed. Protection liner 88 may then be removed, followed by the annealing process 89 (FIG. 34) as shown in FIG. 34. The portions of dipole films 82 on protection liner 88 is then removed, for example, by forming a sacrificial layer to protect lower portions of the dipole films 82, and then remove the sacrificial layer.

Referring to FIG. 34, the dipole dopants in dipole film 82 are driven into the gate dielectric 78 that are on the lower semiconductor nanostructures 26′L through annealing process 89. The corresponding layers incorporating the corresponding dopants are referred to as interfacial layers 78IL′ and high-k dielectric layers 78HK′. Dipole film 82 is then removed.

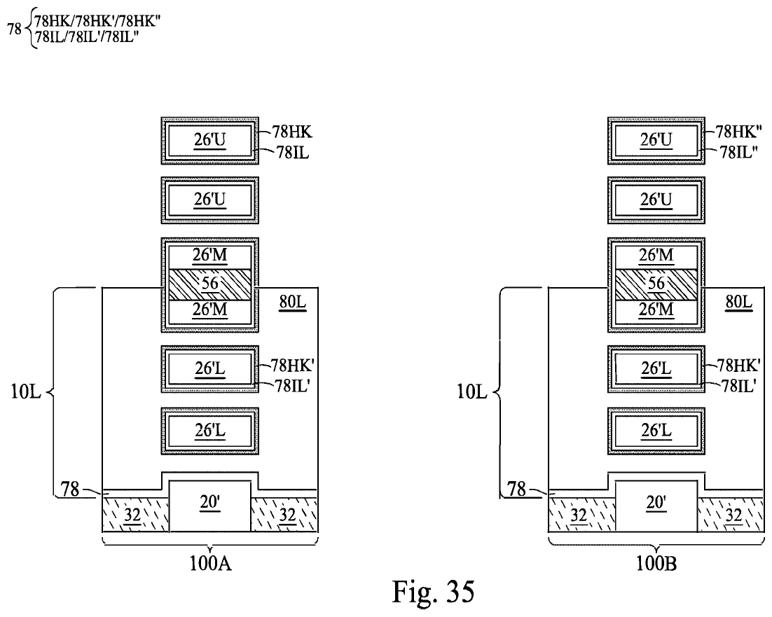

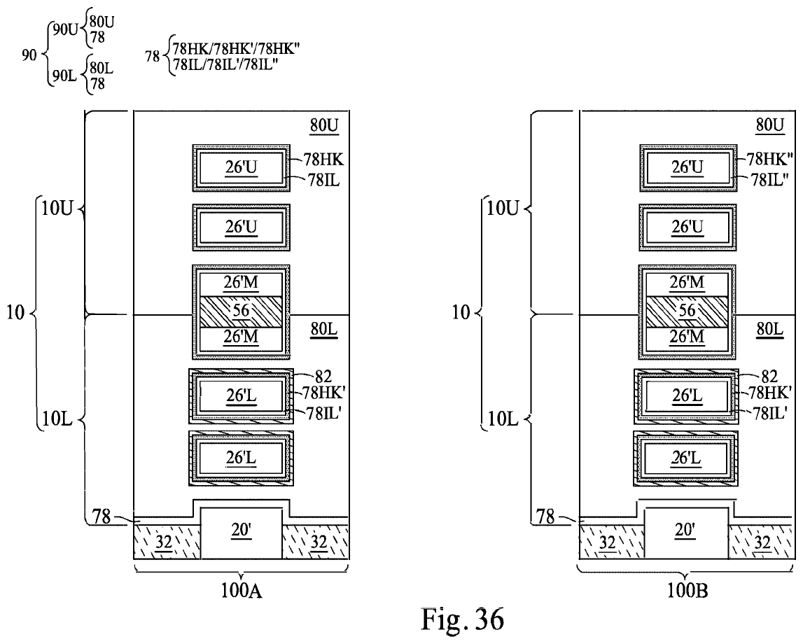

FIGS. 35 through 36 illustrate the formation of lower gate electrodes 80L and upper gate electrodes 80U, respectively, and hence lower FETs 10L and upper FETs 10U are formed, which collectively form CFET 10.

The embodiments of the present disclosure have some advantageous features. By using DSA to form dummy-filling regions, which are used to help the different dipole doping of the upper FETs and the lower FETs of CFETs, the loading in the etch-back of the dummy-filling regions is eliminated. If the loading occurs during the etch-back of the dummy-filling regions, the top surfaces of the dummy-filling regions in device-sparse regions and device-dense regions may be at different levels. This may cause the dipole films to be adversely removed from (or left on) some of the semiconductor nanostructures, which adversely affects the dipole doping processes and the effect of adjusting threshold voltages of FETs.

In accordance with some embodiments of the present disclosure, a method comprises forming a lower semiconductor nanostructure and an upper semiconductor nanostructure overlying the lower semiconductor nanostructure; forming an a lower gate dielectric and an upper gate dielectric on the lower semiconductor nanostructure and the upper semiconductor nanostructure, respectively; dispensing a directed self-assembly material to embed the lower semiconductor nanostructure and the upper semiconductor nanostructure therein; annealing the directed self-assembly material to form dummy filling-regions, wherein the dummy filling-regions comprise a first plurality of layers and a second plurality of layers located alternatingly; recessing the dummy filling-regions, wherein remaining portions of the dummy filling-regions comprise top surfaces lower than the upper semiconductor nanostructure; and doping a dipole dopant into a first one of the upper gate dielectric and the lower gate dielectric.

In an embodiment, the doping the dipole dopant into the first one of the upper gate dielectric and the lower gate dielectric comprises doping the upper gate dielectric. In an embodiment, the doping the dipole dopant into the first one of the upper gate dielectric and the lower gate dielectric comprises doping the lower gate dielectric. In an embodiment, the method further comprises doping an additional dipole dopant into the upper gate dielectric.

In an embodiment, the recessing the dummy filling-regions comprises a plurality of etching cycles, with each of the plurality of etching cycles adopted to remove one of the first plurality of layers and one of the second plurality of layers. In an embodiment, the dispensing the directed self-assembly material comprises dispensing PS-b-PMMA. In an embodiment, the first plurality of layers comprise PS, and the second plurality of layers comprise PMMA.

In an embodiment, the method further comprises, before the directed self-assembly material is dispensed, depositing a first dipole film on the upper gate dielectric and the lower gate dielectric; after the dummy filling-regions are recessed, performing an etching process to remove an upper portion of the first dipole film from the upper gate dielectric; and performing an annealing process to drive a first dipole dopant in the first dipole film into the lower gate dielectric. In an embodiment, the method further comprises, after the annealing process, removing remaining portions of the first dipole film. In an embodiment, the method further comprises, before the annealing process, removing remaining portions of the dummy filling-regions.

In accordance with some embodiments of the present disclosure, a method comprises forming a lower semiconductor nanostructure and an upper semiconductor nanostructure overlapping the lower semiconductor nanostructure; forming a lower gate dielectric and an upper gate dielectric on the lower semiconductor nanostructure and the upper semiconductor nanostructure, respectively; depositing a first dipole film on the upper gate dielectric and the lower gate dielectric; dispensing a directed self-assembly material to embed the first dipole film; annealing the directed self-assembly material to form dummy filling-regions, wherein the dummy filling-regions comprise a first plurality of layers and a second plurality of layers located alternatingly; recessing the dummy filling-regions to reveal an upper portion of the first dipole film, wherein the upper portion is on the upper gate dielectric; etching the upper portion of the first dipole film; and performing a first annealing process to drive a first dipole dopant in a lower portion of the first dipole film into the lower gate dielectric.

In an embodiment, the method further comprises forming a lower source/drain region aside of and connecting to the lower semiconductor nanostructure; and forming an upper source/drain region aside of and connecting to the upper semiconductor nanostructure. In an embodiment, the dispensing the directed self-assembly material comprises dispensing PS-b-PMMA. In an embodiment, the first plurality of layers comprises PS, and the second plurality of layers comprise PMMA.

In an embodiment, the method further comprises forming a lower gate electrode on the lower gate dielectric; depositing a second dipole film on the upper gate dielectric; and performing a second annealing process to drive a second dipole dopant in the second dipole film into the upper gate dielectric. In an embodiment, the method further comprises forming a protection liner over the dummy filling-regions, wherein the dummy filling-regions have been recessed to reveal the upper gate dielectric, wherein when the first annealing process is performed, the protection liner is on the upper gate dielectric.

In accordance with some embodiments of the present disclosure, a method comprises forming a lower semiconductor nanostructure and an upper semiconductor nanostructure overlapping the lower semiconductor nanostructure; dispensing PS-b-PMMA to cover the lower semiconductor nanostructure and the upper semiconductor nanostructure; annealing the PS-b-PMMA to form a plurality of PS layers and a plurality of PMMA layers that are located alternatingly; using the plurality of PS layers and the plurality of PMMA layers as a mask to form a dipole film encircling a first one of the lower semiconductor nanostructure and the upper semiconductor nanostructure; and driving a first dipole dopant in the dipole film into a gate dielectric on the first one of the lower semiconductor nanostructure and the upper semiconductor nanostructure.

In an embodiment, the method further comprises, before the driving, performing first etching cycles to remove upper parts of the plurality of PS layers and a plurality of PMMA layers. In an embodiment, the method further comprises after the first etching cycles, performing a patterning process on the dipole film, and after the patterning process, performing second etching cycles to remove lower parts of the plurality of PS layers and a plurality of PMMA layers. In an embodiment, the method further comprises forming a lower source/drain region aside of and connecting to the lower semiconductor nanostructure; and forming an upper source/drain region aside of and connecting to the upper semiconductor nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower semiconductor nanostructure and an upper semiconductor nanostructure overlying the lower semiconductor nanostructure;
forming a lower gate dielectric and an upper gate dielectric on the lower semiconductor nanostructure and the upper semiconductor nanostructure, respectively;
forming a dummy filling-region comprising:
forming a first plurality of layers comprising a first material; and
forming a second plurality of layers comprising a second material different from the first material, wherein the first plurality of layers and the second plurality of layers are located alternatingly, and wherein the lower gate dielectric and the upper gate dielectric are in the first plurality of layers and the second plurality of layers; and
recessing the dummy filling-region, wherein a remaining portion of the dummy filling-region comprises a top surface lower than the upper semiconductor nanostructure.

2. The method of claim 1, wherein the forming the dummy filling-region comprises:
forming a material layer; and
separating the material layer as the first plurality of layers and the second plurality of layers.

3. The method of claim 2, wherein the forming the dummy filling-region comprises:
dispensing a directed self-assembly material as the material layer; and
annealing the directed self-assembly material to form poly(styrene) (PS) layers as the first plurality of layers, and poly(methyl methacrylate) (PMMA) as the second plurality of layers.

4. The method of claim 1 further comprising doping a dipole dopant into one of the lower gate dielectric and the upper gate dielectric.

5. The method of claim 4, wherein the dipole dopant is doped into the lower gate dielectric.

6. The method of claim 4, wherein the dipole dopant is doped into the upper gate dielectric.

7. The method of claim 1, wherein the recessing the dummy filling-region comprises a plurality of etching cycles, with each of the plurality of etching cycles adopted to remove one of the first plurality of layers and one of the second plurality of layers.

8. The method of claim 1, wherein the first plurality of layers comprise polystyrene (PS), and the second plurality of layers comprise poly(methyl methacrylate) (PMMA).

9. The method of claim 1 further comprising:
before the dummy filling-region is formed, depositing a dipole film on the upper gate dielectric and the lower gate dielectric;
after the dummy filling-region is recessed, performing an etching process to remove an upper portion of the dipole film from the upper gate dielectric; and
performing an annealing process to drive a first dipole dopant in the dipole film into the lower gate dielectric.

10. The method of claim 9 further comprising, after the annealing process, removing remaining portions of the dipole film.

11. The method of claim 9 further comprising, before the annealing process, removing remaining portions of the dummy filling-region.

12. A method comprising:
forming a lower semiconductor nanostructure and an upper semiconductor nanostructure overlapping the lower semiconductor nanostructure;
forming a lower gate dielectric and an upper gate dielectric on the lower semiconductor nanostructure and the upper semiconductor nanostructure, respectively;
depositing a first dipole film on the lower gate dielectric and the upper gate dielectric;
forming a first layer comprising a first material;
forming a second layer over the first layer, wherein the second layer comprises a second material different from the first material, wherein the second layer is at a first level lower than a top surface of the lower gate dielectric, and wherein a part of the lower gate dielectric is in the first layer and the second layer;
forming a third layer over the second layer, the third layer comprising the first material;
forming a fourth layer over the third layer, the fourth layer comprising the second material, wherein the fourth layer is at a second level higher than a bottom surface of the upper gate dielectric;
removing the fourth layer and the third layer, wherein the first layer and the second layer remain;
etching an upper portion of the first dipole film; and
performing an annealing process to drive a first dipole dopant in a lower portion of the first dipole film into the lower gate dielectric.

13. The method of claim 12, wherein the removing the fourth layer and the third layer comprises:
etching the fourth layer using the third layer as an etch stop layer; and
etching the third layer to reveal an underlying layer.

14. The method of claim 12 further comprising:
forming a lower source/drain region on a side of and connecting to the lower semiconductor nanostructure; and
forming an upper source/drain region on a side of and connecting to the upper semiconductor nanostructure.

15. The method of claim 12, wherein the first layer and the second layer are formed by processes comprising:
dispensing poly(styrene)-block-poly(methyl methacrylate) (PS-b-PMMA); and
performing an additional annealing process to separate the first layer and the second layer from each other, wherein the first layer comprises poly(styrene) (PS), and the second layer comprises poly(methyl methacrylate) (PMMA).

16. The method of claim 12 further comprising:
forming a lower gate electrode on the lower gate dielectric;
depositing a second dipole film on the upper gate dielectric; and
driving a second dipole dopant in the second dipole film into the upper gate dielectric.

17. The method of claim 12, wherein the first layer, the second layer, the third layer, and the fourth layer are planar layers.

18. A method comprising:
forming a lower semiconductor nanostructure and an upper semiconductor nanostructure overlapping the lower semiconductor nanostructure;
forming a plurality of layers comprising horizontal portions, wherein the horizontal portions extend from a first side to an opposite second side of the lower semiconductor nanostructure and the upper semiconductor nanostructure, and wherein the plurality of layers comprise:
first layers formed of a first material; and
second layers formed of a second material different from the first material, wherein the first layers and the second layers are allocated alternatingly;
using the first layers and the second layers as a mask to form a dipole film, wherein the dipole film encircles one of the lower semiconductor nanostructure and the upper semiconductor nanostructure; and
driving a dipole dopant in the dipole film into a gate dielectric on a corresponding one of the lower semiconductor nanostructure and the upper semiconductor nanostructure.

19. The method of claim 18 further comprising, after the dipole dopant is driven into the gate dielectric, removing remaining portions of the first layers and the second layers.

20. The method of claim 18 further comprising:
dispensing poly(styrene)-block-poly(methyl methacrylate) (PS-b-PMMA) to cover the lower semiconductor nanostructure and the upper semiconductor nanostructure; and
annealing the PS-b-PMMA to form a plurality of poly(styrene) (PS) layers as the first layers, and a plurality of poly(methyl methacrylate) (PMMA) layers as the second layers.
